(19) United States
(12) Patent Application Publication
(10) Pub. No.: US 2008/0157256 A1
(43) Pub. Date: Jul. 3, 2008

(54) CMOS IMAGE SENSOR AND METHOD OF MANUFACTURING THEREOF

(76) Inventor: Tae-Gyu Kim, Gyeongsangnam-do (KR)

Correspondence Address: SHERR & NOURSE, PLLC, 620 HERNDON PARKWAY, SUITE 200, HERNDON, VA, 20170, US

(21) Appl. No.: 11/964,435

(22) Filed: Dec. 26, 2007

(30) Foreign Application Priority Data
Dec. 29, 2006 (KR) 10-2006-0137350

(51) Int. Cl. H01L 31/09

(52) U.S. Cl. 257/461; 438/57; 257/E31.093

(57) ABSTRACT

A CMOS image sensor adapted to remove a dead zone and preventing occurrence of dark current. The CMOS image sensor can an epi layer defined by at least a photodiode region and a device isolation region formed over a semiconductor substrate; a device isolation film formed in the device isolation region; a gate electrode formed over the epi layer; and a contact plug overlapping a portion of the photodiode region and a portion of the gate electrode.

The present application claims priority under 35 U.S.C. 119 to Korean Patent Application No. 10-2006-0137350, filed on Dec. 29, 2006, which is hereby incorporated by reference in its entirety.

### BACKGROUND

An image sensor is a device for converting an optical image to an electric signal. Image sensors may be categorized generally as complementary metal-oxide-silicon image sensors (CMOS) and charge coupled device CCS image sensors.

Comparatively, CCD image sensors may exhibit enhanced photosensitivity and lower noise than CMOS image sensors but has difficulty achieving high integration density and low power consumption. On the contrary, CMOS image sensors has simple manufacturing processes and may be more suitable for achieving high integration density and low power consumption.

Aspects of semiconductor device fabricating technology have focused on developing CMOS image sensors due to improved fabricating technology and characteristics of CMOS image sensors. Each pixel of a CMOS image sensor may include a plurality of photodiodes for receiving light and a plurality of transistors for controlling inputted video signals.

CMOS image sensors may be categorized in accordance with the number of transistors, such as a 3T-type, a 4T-type, etc. A 3T-type CMOS image sensor may include a photodiode and three transistors while a 4T-type image sensor may include a photodiode and four transistors.

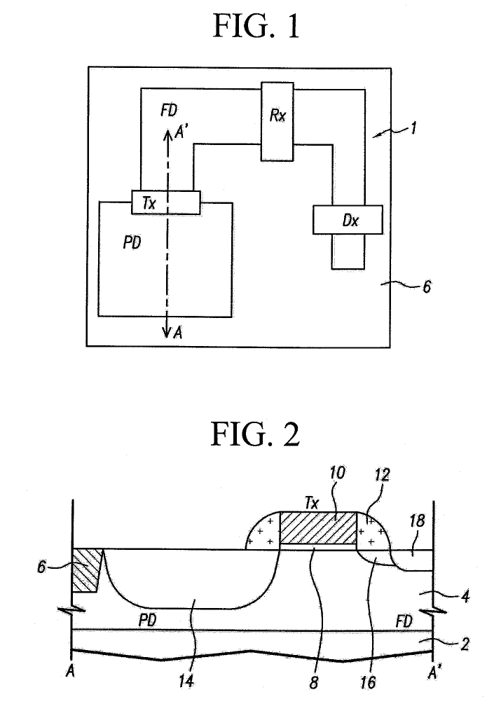

As illustrated in example FIG. 1, a 4T-type CMOS image sensor may include photodiode region PD, transfer transistor Tx, reset transistor Rx, and drive transistor Dx. Photodiode region PD may be formed in a widest portion of active area 1. Transfer transistor Tx, reset transistor Rx, and drive transistor Dx may be formed overlapping active area 1 except photodiode region PD. The description of selection transistor Sx will be omitted.

Photodiode PD detects incident light and generates charges according to the intensity of light. Transfer transistor Tx carries the charges generated at photodiode PD to floating diffusion area FD. Reset transistor Rx discharges charges stored in floating diffusion region FD in order to detect a signal. Drive transistor Dx may function as a source follower for converting the charges received from photodiodes PD into a voltage signal.

As illustrated in example FIG. 2, the CMOS image sensor may further includes P⁺-type semiconductor substrate 2, P-type epi layer 4, device isolation film 6, gate electrode 10, n-type diffusion area 14, gate spacer 12, lightly doped drain (LDD) region 16, and n⁺-type diffusion area 18.

P⁺-type semiconductor substrate 2 may be defined by photodiode area PD, active area 1, and the device isolation area. P-type epi layer 4 may be formed on and/or over semiconductor substrate 2. Device isolation film 6 may be formed in the device isolation area. Gate electrode 10 may be formed on and/or over epi layer 4 with gate insulating film 8 interposed therebetween. n-type diffusion area 14 may be formed in epi layer 4 of photodiode region PD. Gate spacer 12 may be formed on at least one sidewall of gate electrode 10. LDD region 16 is formed in active area 1 among transfer transistor Tx, reset transistor Rx, and drive transistor Dx. n⁺-type diffusion area 18 may be formed by implanting n⁺-type dopant ions into epi layer 4 of floating diffusion region FD.

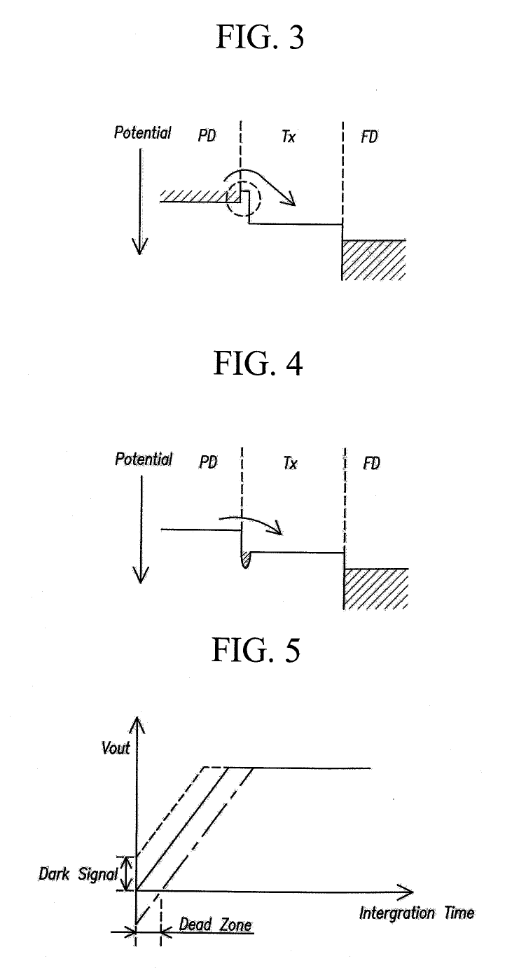

As illustrated in example FIGS. 3 and 4, in such a CMOS image sensor, a potential barrier or a potential pocket may be formed in an interface between photodiode region PD and transfer transistor Tx. Thus, electrons generated at photodiode region PD may stay in the potential pocket, and thus, may not be delivered into floating diffusion region FD through transfer transistor Tx. Thus, a time delay may occur.

As illustrated in example FIG. 5 illustrates a graph showing voltage vs. time characteristic of the CMOS image sensor illustrated in example FIGS. 1 and 2. Example FIG. 5 illustrates a dead zone, in which a signal is not output although a signal is input, appears and a dark signal is generated by the time delay, due to the potential barrier and the potential pocket.

In order to such problems, a method of increasing a drive voltage of transfer transistor Tx or reducing a dose of dopant ions implanted into a channel region of transfer transistor Tx may be used. However, in such a method, dark current is increased.

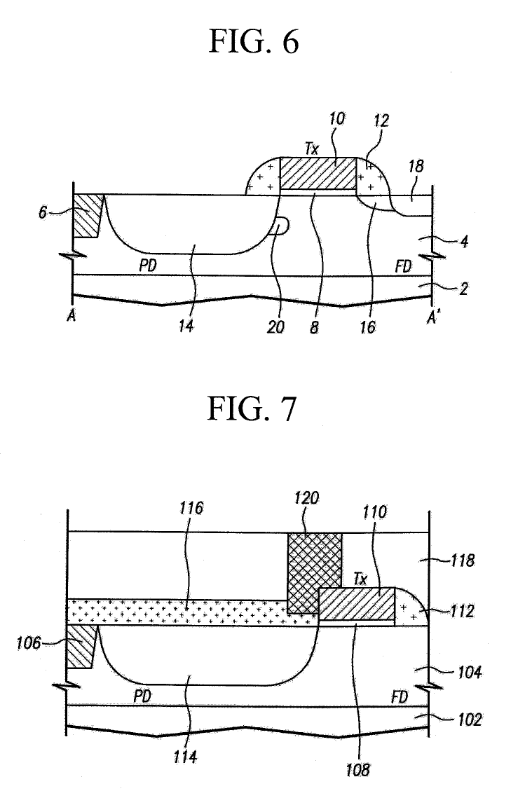

As illustrated in example FIG. 6, another method attempted to solve the problem includes n-type dopant ions being obliquely implanted into a region located below transfer transistor Tx to form second n-type diffusion region 20. However, even when second n-type diffusion region 20 is formed, dark current is still increased.

### SUMMARY

Embodiments relate to a CMOS image sensor and a method of manufacturing thereof capable of removing a dead zone and preventing occurrence of dark current.

Embodiments relate to a CMOS image sensor that can include at least one of the following: an epi layer defined by at least a photodiode region and a device isolation region formed over a semiconductor substrate; a device isolation film formed in the device isolation region; a gate electrode formed over the epi layer; and a contact plug overlapping a portion of the photodiode region and a portion of the gate electrode.

Embodiments relate to a CMOS image sensor that can include at least one of the following: an epi layer defined by at least a photodiode region and a device isolation region formed over a semiconductor substrate; a device isolation film formed in the device isolation region; an n-type diffusion region formed in the photodiode region of the epi layer; and a gate electrode formed over the epi layer and partially overlapping the n-type diffusion region.

Embodiments relate to a method of manufacturing a CMOS image sensor that can include at least one of the following steps: forming an epi layer defined by at least a photodiode region and a device isolation region over a semiconductor substrate; forming a device isolation film in the device isolation region; forming a gate electrode over the epi layer; and then forming a contact plug overlapping a portion of the photodiode region and a portion of the gate electrode.

### DRAWINGS

Example FIGS. 1 to 6 illustrate a CMOS image sensor and graphs relating to such a CMOS image sensor.

Example FIGS. 7 to 10 illustrate a CMOS image sensor in accordance with embodiments.

### DESCRIPTION

As illustrated in example FIG. 7, a CMOS image sensor in accordance with embodiments can include P-type epi layer 104 defined by photodiode region PD, an active region, and a device isolation region formed on and/or over semiconductor substrate 102. Semiconductor substrate 102 can be a P⁺-type substrate. Device isolation film 106 is formed in a device isolation region of epi layer 104. Gate electrode 110 can be formed on and/or over epi layer 104 with gate insulating film 108 interposed therebetween. N-type diffusion region 114 is formed in photodiode region PD of epi layer 104. Gate spacer 112 can be formed on a sidewall of gate electrode 110 on and/or over floating diffusion region FD.

First insulating film 116 can be formed on and/or over photodiode region PD and can include step difference portion 116a formed in photodiode region PD adjacent to transfer transistor Tx. Step difference portion 116a can be formed in photodiode region PD adjacent to transfer transistor Tx and can have a thickness smaller than the other portion of first insulating film 116. Step difference portion 116a can be advantageous for reducing the potential barrier generated between transfer transistor Tx and photodiode region PD. Accordingly, electrons generated at photodiode region PD are easily delivered into floating diffusion region FD to remove a dead zone. Reset can be more perfectly achieved at the time of reset processing and a dark signal characteristic can be improved.

Second interlayer insulating film 118 can be formed on and/or over epi layer 104 including gate electrode 110 and first insulating film 116. Contact hole 121 may be formed extending through second interlayer insulating film 118 exposing the uppermost surface of step difference portion 116a of first insulating film 116 and also the uppermost surface of gate electrode 110. Contact plug 120 can then be formed in contact hole 121 second interlayer insulating film 118 to overlap photodiode region PD adjacent to transfer transistor Tx. Accordingly, a potential barrier generated between photodiode region PD and transfer transistor Tx can be reduced by overlapped contact plug 120.

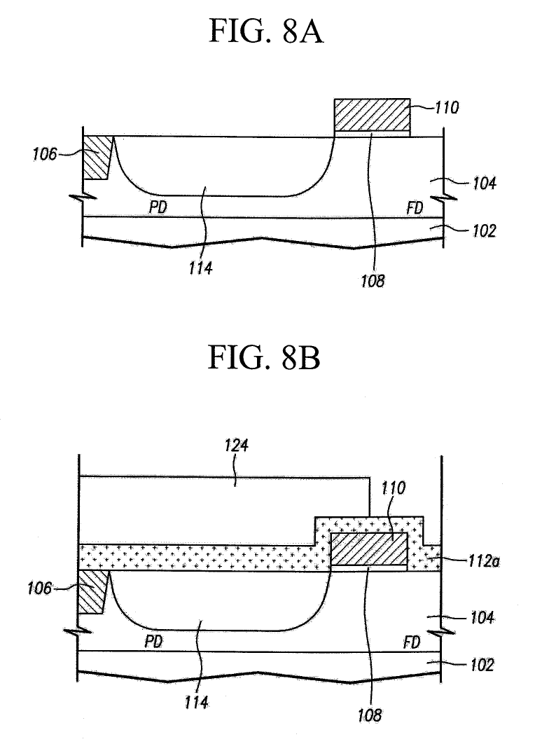

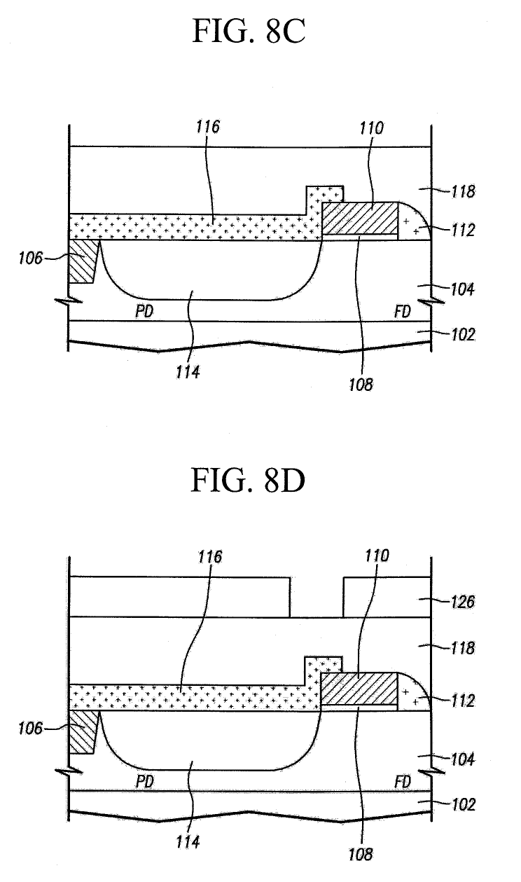

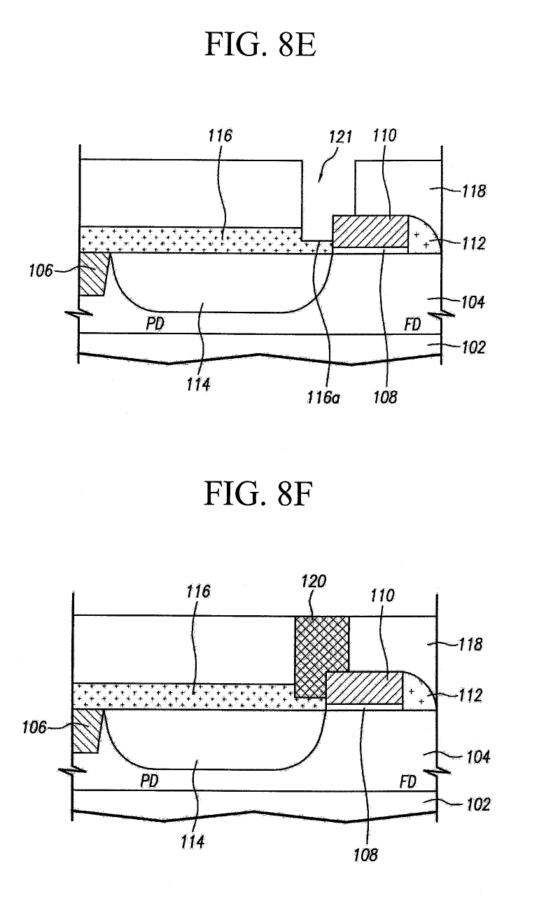

As illustrated in example FIG. 8A, a method of manufacturing the CMOS image sensor previously described can include forming low-concentration P-type epi layer 104 on and/or over P⁺-type semiconductor substrate 102 using an epitaxial process. Gate insulating film 108 and gate electrode 110 of transfer transistor Tx can then be sequentially formed on and/or over epi layer 104. In more detail, a gate insulating film and a gate metal layer can be sequentially formed on and/or over epi layer using a deposition method. The gate insulating film and the gate metal layer can then be patterned by a photolithographic process using a mask to form gate insulating film 108 and gate electrode 110. A photoresist pattern can then be formed to expose photodiode region PD of epi layer 104. N-type dopant ions can then be implanted into exposed photodiode region PD to form n-type diffusion region 114.

As illustrated in example FIG. 8B, silicon nitride (SiN) layer 112a can then be formed on and/or over the entire surface of epi layer 104 including gate electrode 110. Photoresist pattern 124 can then be formed on and/or over a portion of silicon nitride layer 112a that partially overlaps the uppermost surface of gate electrode 110. An etch-back process using photoresist pattern 124 can then be performed.

As illustrated in example FIG. 8C, gate spacer 112 can then be formed on one sidewall of gate electrode 110. First insulating film 116 can then be formed in photodiode region PD partially overlaps the uppermost surface of gate electrode 110. Second interlayer insulating film 118 can then be formed on and/or over epi layer 104 including gate electrode 110 and first insulating film 116.

As illustrated in example FIGS. 8D and 8E, photoresist pattern 126 can then be formed on and/or over a portion of second interlayer insulating film 118. Particularly, photoresist pattern 126 can be formed such that a portion of second interlayer insulating film 118 corresponding to first insulating film 116 which overlaps gate electrode 110 can be exposed. Second interlayer insulating film 118 can then be etched using a dry etching method using photoresist pattern 126 as a mask to form contact hole 121.

As illustrated in example FIG. 8F, the portion of first insulating film 116 which overlaps gate electrode 110 can then be removed and, simultaneously, first insulating film 116 corresponding to a portion of n-type diffusion region 114 adjacent to gate electrode 110 can be etched to form step difference portion 116a.

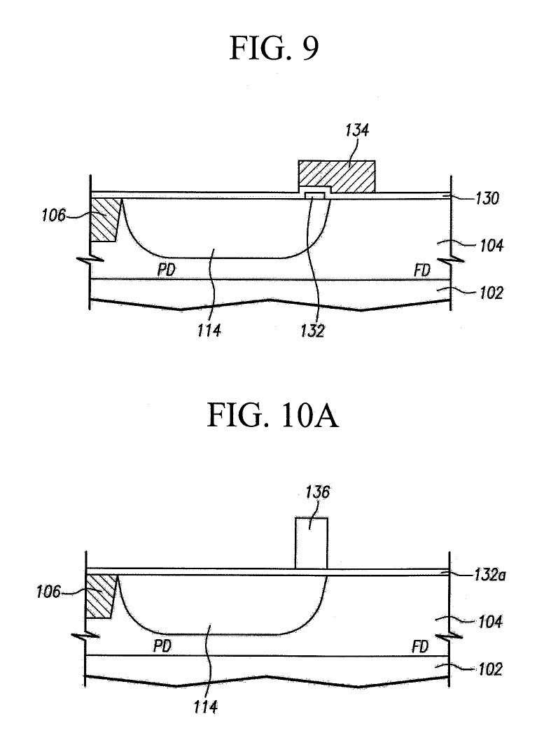

As illustrated in example FIG. 9, a CMOS image sensor in accordance with embodiments can include semiconductor substrate 102, a P-type epi layer 104, a device isolation film 106, an n-type diffusion region 114, a gate electrode 134, a gate insulating film 132, and a gate oxide film 130. Here, in accordance with embodiments illustrated in example FIG. 9, the same components illustrated in example FIG. 7 are denoted by the same reference numerals.

Semiconductor substrate 102 can be a P⁺-type substrate defined by photodiode region PD, an active region, and a device isolation region. P-type epi layer 104 can be formed on and/or over semiconductor substrate 102. Device isolation film 106 can then be formed in the device isolation region. N-type diffusion region 114 can then be formed in photodiode region PD of epi layer 104.

Gate electrode 134 can then be formed to partially overlap n-type diffusion region 114. Gate insulating film 132 can be formed under the portion of gate electrode 134 which overlaps n-type diffusion region 114. Gate insulating film 132 can be composed of silicon oxide (SiO₂). Gate oxide film 130 can be formed on and/or over entire surface of epi layer 104 including gate insulating film 132. Gate electrode 134 can be formed to overlap photodiode region PD adjacent to transfer transistor Tx. Accordingly, a potential barrier generated between photodiode region PD and transfer transistor Tx can be reduced by overlapped gate electrode 134. Because gate insulating film 132 and gate oxide film 130 can be formed in photodiode region PD which overlaps gate electrode 134, electrons generated at photodiode region PD can be easily delivered into floating diffusion region FD to remove a dead zone. Reset can be more perfectly achieved at the time of reset processing and a dark signal characteristic can be improved.

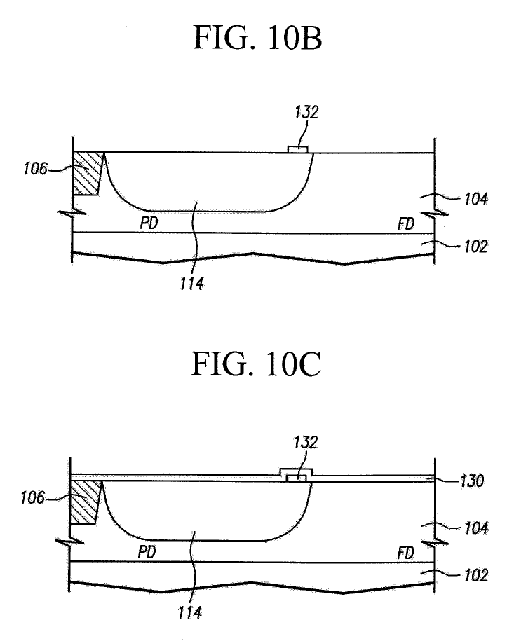

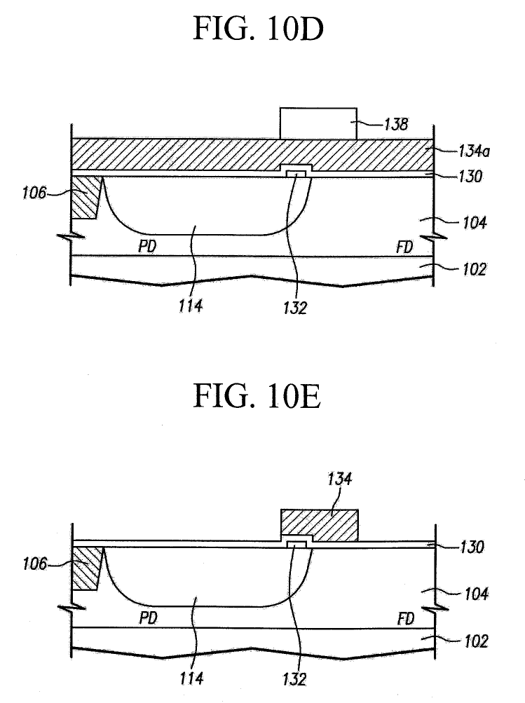

As illustrated in example FIG. 10A, a method of manufacturing the CMOS image sensor can include forming low-concentration P-type epi layer 104 on and/or over P⁺-type semiconductor substrate 102 using an epitaxial process. A photoresist pattern can then be formed over epi layer 104 such that photodiode region PD of epi layer 104 is exposed. N-type dopant ions can then be implanted into exposed photodiode region PD to form n-type diffusion region 114. The photoresist pattern can then be removed by a stripping process.

As illustrated in example FIGS. 10B and 10C, gate insulating layer 132a can then be deposited on and/or over the entire surface of epi layer 104. Photoresist pattern 136 can then be formed on and/or over gate insulating film 132a in a region corresponding to a portion of photodiode region PD which will overlap gate electrode 134. Gate insulating layer 132 can then be patterned using a dry etching method using photoresist pattern 136 as a mask. Photoresist pattern 136 can then be removed by a stripping process. Gate oxide film 130 can then be formed on and/or over the entire surface of epi layer 104 including gate insulating film 132 using an oxidation process.

As illustrated in example FIGS. 10D and 10E, gate metal layer 134a can then be formed on and/or over gate insulating film 132. Photoresist pattern 138 can then be formed on and/or over gate metal layer 134a. Gate metal layer 134a can then be patterned using a photolithography process using photoresist pattern 138 as a mask to form gate electrode 134 partially overlapping photodiode region PD.

In accordance with embodiments, because a contact plug or a gate electrode can be formed overlapping photodiode region PD adjacent to transfer transistor Tx, a potential barrier generated between photodiode region PD and transfer transistor Tx can be reduced. Accordingly, electrons generated at photodiode region PD can be easily delivered into floating diffusion region FD to remove a dead zone. In addition, reset can be more perfectly achieved at the time of reset processing and a dark signal characteristic can be enhanced. Even still, since electrons generated at photodiode region PD can be collected in a potential well region can reduce the probability of electrons moving from a place far from transfer transistor Tx during movement. Thus, sensitivity of a sensor can be improved.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
an epi layer defined by at least a photodiode region and a device isolation region formed over a semiconductor substrate;
a device isolation film formed in the device isolation region;
a gate electrode formed over the epi layer; and
a contact plug overlapping a portion of the photodiode region and a portion of the gate electrode.

2. The apparatus of claim 1, further comprising an n-type diffusion region formed in the photodiode region.

3. The apparatus of claim 2, further comprising a gate spacer formed against at least one sidewall of the gate electrode.

4. The apparatus of claim 3, further comprising an insulating film formed over the epi layer.

5. The apparatus of claim 4, wherein the insulating film includes a first insulating film portion and a second insulating film contacting the gate electrode.

6. The apparatus of claim 5, wherein the first insulating film portion has a thickness greater than the thickness of the second insulating film portion.

7. The apparatus of claim 6, further comprising an interlayer insulating film formed over the epi layer including the gate electrode, the gate spacer and the insulating film.

8. The apparatus of claim 7, further comprising a contact hole extending through the interlayer insulating film and exposing the uppermost surface of the second insulating film portion and a portion of the gate electrode.

9. The apparatus of claim 8, wherein the contact plug is formed in the contact hole.

10. The apparatus of claim 1, further comprising a gate insulating film interposed between the gate electrode and the epi layer.

11. An apparatus comprising:
an epi layer defined by at least a photodiode region and a device isolation region formed over a semiconductor substrate;
a device isolation film formed in the device isolation region;
an n-type diffusion region formed in the photodiode region of the epi layer; and
a gate electrode formed over the epi layer and partially overlapping the n-type diffusion region.

12. The apparatus of claim 11, further comprising:
a gate insulating film formed under a portion of the gate electrode; and
a gate oxide film formed over the uppermost surface of the epi layer including the gate insulating film.

13. A method comprising:
forming an epi layer defined by at least a photodiode region and a device isolation region over a semiconductor substrate;
forming a device isolation film in the device isolation region;
forming a gate electrode over the epi layer; and then forming a contact plug overlapping a portion of the photodiode region and a portion of the gate electrode.

14. The method of claim 13, further comprising forming an n-type diffusion region in the photodiode region.

15. The method of claim 14, further comprising forming a gate spacer against at least one sidewall of the gate electrode.

16. The method of claim 15, further comprising forming an insulating film over the epi layer.

17. The method of claim 16, wherein the insulating film includes a first insulating film portion and a second insulating film contacting the gate electrode.

18. The method of claim 17, wherein the first insulating film portion has a thickness greater than the thickness of the second insulating film portion.

19. The method of claim 18, further comprising forming an interlayer insulating film over the epi layer including the gate electrode, the gate spacer and the insulating film.

20. The method of claim 19, further comprising:
forming a contact hole extending through the interlayer insulating film and exposing the uppermost surface of the second insulating film portion and a portion of the gate electrode, wherein the contact plug is formed in the contact hole.
